(19) United States
(12) Patent Application Publication
(10) Pub. No.: US 2021/0074736 A1
(43) Pub. Date: Mar. 11, 2021

(54) SEMICONDUCTOR DEVICE

(71) Applicant: Japan Display Inc., Tokyo (JP)

(72) Inventors: Akihiro HANADA, Tokyo (JP); Toshihide JINNAI, Tokyo (JP); Hajime WATAKABE, Tokyo (JP); Ryo ONODERA, Tokyo (JP)

(73) Assignee: Japan Display Inc., Tokyo (JP)

(21) Appl. No.: 16/996,920

(22) Filed: Aug. 19, 2020

(30) Foreign Application Priority Data
Sep. 5, 2019 (JP) 2019-161733

(51) Int. Cl. H01L 27/12; H01L 29/786; G02F 1/1362; G02F 1/1368

(52) U.S. Cl. CPC H01L 27/1225; H01L 27/124; H01L 29/78633; H01L 27/3262; G02F 1/136286; G02F 1/1368; H01L 29/7869

(57) ABSTRACT

The purpose of the present invention is to prevent the TFT in the semiconductor device is shorted by existence of a foreign substance. An example of the structure to solve the problem is:
A semiconductor device comprising:
a scan line extends in a first direction,
a first signal line extends in a second direction, which crosses the first direction,
a second signal line extends parallel to the first signal line,
an electrode is disposed between the first signal line and the second signal line,
wherein a first TFT connects with the second signal line in a vicinity of the second signal line, a second TFT connects with the electrode in a vicinity of the first signal line,
the first TFT and the second TFT are formed from oxide semiconductors,
the first TFT and the second TFT are connected in series.

### CLAIM OF PRIORITY

The present application claims priority from Japanese Patent Application JP 2019-161733 filed on Sep. 5, 2019, the content of which is hereby incorporated by reference into this application.

### BACKGROUND OF THE INVENTION

### (1) Field of the Invention

The present invention relates to semiconductor devices, including display devices and photo-sensor devices and so forth, which use TFTs formed from oxide semiconductors.

### (2) Description of the Related Art

The TFT (Thin Film Transistor) formed from oxide semiconductor has a large OFF resistance compared with the TFT formed from polysilicon, and has larger mobility of carriers compared with the TFT formed from a-Si (Amorphous silicon); thus, the TFT formed from oxide semiconductor can be used in the display devices such as a liquid crystal display device and an organic EL display devices and so forth, or semiconductor devices such as a sensor and so forth.

If TFTs have defects in those devices, bright points, dark points, in some cases, bright lines, black lines and so forth are generated; consequently, those display devices become defective. It is conceivable to put plural TFTs in one pixel to avoid those problems. Patent document 1 discloses to put a plural TFTs in each of the pixels to avoid pixel defects due to defects of TFTs on a TFT substrate, in which a-Si TFTs are used for switching transistors in the pixels.

### PRIOR ART DOCUMENT

### Patent Document

Patent document 1: Japanese patent application laid open No. Sho 64-50028

### SUMMARY OF THE INVENTION

If oxygen is extracted from a channel of the oxide semiconductor film, a resistance of the channel decreases, consequently, the oxide semiconductor TFT is shorted. The phenomenon that oxygen is extracted from the oxide semiconductor occurs when foreign bodies like fine particles of metal or insulating material exist in the vicinity of the TFT. Namely, the defective oxide semiconductor TFT is generated not only when the foreign substance exists on the TFT but when the foreign substance exists in the vicinity of the TFT. This kind of defect by the foreign particles in the oxide semiconductor TFTs is very different from the defect by the foreign particles in the conventional TFTs. The size of the foreign bodies in this case is typically 1 to 2 microns, which is smaller compared with the foreign bodies conventionally thought as problematic.

Therefore, in the oxide semiconductor TFT, only a redundancy of the TFTs does not solve the pixel defects due to foreign substances. By the way, the oxide semiconductor TFT can be used as a switching TFT or controlling TFT in a semiconductor device as well as in a display device. The semiconductor device also has the same problem as explained above for the display device.

The purpose of the present invention is to avoid defects that the oxide semiconductor is shorted in the pixel of the display device or in the element of the semiconductor device, which uses the oxide semiconductor TFT for switching or for controlling.

The present invention solves the above explained problems; the concrete measures are as follows.

(1) A semiconductor device comprising:

a scan line extending in a first direction,

a first signal line extending in a second direction, which crosses the first direction,

a second signal line, which extends parallel to the first signal line,

an electrode disposed between the first signal line and the second signal line,

wherein a first TFT connects with the second signal line in a vicinity of the second signal line, a second TFT connects with the electrode in a vicinity of the first signal line,

the first TFT and the second TFT are formed from oxide semiconductors,

the first TFT and the second TFT are connected in series.

(2) A semiconductor device comprising:

a scan line extending in a first direction,

a first signal line extending in a second direction, which crosses the first direction,

a second signal line, which extends parallel to the first signal line,

a third signal line, which extends parallel to the second signal line,

a first electrode, disposed between the first signal line and the second signal line,

a second electrode, disposed between the second signal line and the third signal line,

wherein a first TFT connects with the third signal line in a vicinity of the third signal line, a second TFT connects with the first electrode in a vicinity of the first signal line,

the first TFT and the second TFT are formed from oxide semiconductors,

the first TFT and the second TFT are connected in series.

(3) A semiconductor device comprising:

a first scan line, a second scan line and a third scan line extending in a first direction and arranged with a distance L1 to each other,

a first signal line and a second signal line extending in a second direction that crosses the first direction with a distance W to each other,

an electrode formed between the second scan line and the third scan line and between the first signal line and the second signal line,

wherein a first TFT that connects with the first signal line exists near the first signal line and between the first scan line and the second scan line,

a second TFT that connects with the electrode exists near an intersection of the first signal line and the second scan line,

provided a distance between a center of the second scan line and a center of a channel of the first TFT in the second direction is L2,

L2≥0.5L1

the first TFT and the second TFT are formed from oxide semiconductors,

the first TFT and the second TFT are connected in series.

### BRIEF DESCRIPTION OF THE DRAWINGS

FIG. 1 is a plan view of the liquid crystal display device;

FIG. 2 is a plan view of the display area of the liquid crystal display device;

FIG. 3 is a cross sectional view of the display area of the liquid crystal display device;

FIG. 4 is a plan view that shows a problem of oxide semiconductor TFT;

FIG. 5 is a plan view that shows another problem of oxide semiconductor TFT;

FIG. 6 is an equivalent circuit of FIG. 5;

FIG. 7 is a plan view of a structure of embodiment 1;

FIG. 8 is a plan view of another structure of embodiment 1;

FIG. 9 is an equivalent circuit of FIG. 8;

FIG. 10 is a cross sectional view of FIG. 7 along the line A-A;

FIG. 11 is a plan view of still another structure of embodiment 1;

FIG. 12 is an equivalent circuit of still yet another structure of embodiment 1;

FIG. 13 is a plan view of a structure of embodiment 2;

FIG. 14 is a plan view of another structure of embodiment 2;

FIG. 15 is an equivalent circuit of FIG. 14;

FIG. 16 is a plan view of still another structure of embodiment 2;

FIG. 17 is a plan view of a structure of embodiment 3;

FIG. 18 is a plan view of another structure of embodiment 3;

FIG. 19 is a plan view of still another structure of embodiment 3;

FIG. 20 is a plan view of a structure of embodiment 4;

FIG. 21 is a plan view of another structure of embodiment 4;

FIG. 22 is a plan view of a structure of embodiment 5;

FIG. 23 is a cross sectional view of FIG. 22 along the line B-B;

FIG. 24 is a plan view of a structure of embodiment 6;

FIG. 25 is a cross sectional view of FIG. 24 along the line C-C;

FIG. 26 is an equivalent circuit of a general organic EL display device;

FIG. 27 is an equivalent circuit of pixel portion of the organic EL display device according to embodiment 7;

FIG. 28 is a cross sectional view of another structure of the display device according to embodiment 7;

FIG. 29 is a cross sectional view of another structure of the display device according to embodiment 7;

FIG. 30 is a cross sectional view of still another structure of the display device according to embodiment 7;

FIG. 31 is a cross sectional view of detecting area of the photo sensor device;

FIG. 32 is a plan view of the photo sensor device.

### DETAILED DESCRIPTION OF THE PREFERRED EMBODIMENTS

The present invention is explained in the following embodiments in detail.

### Embodiment 1

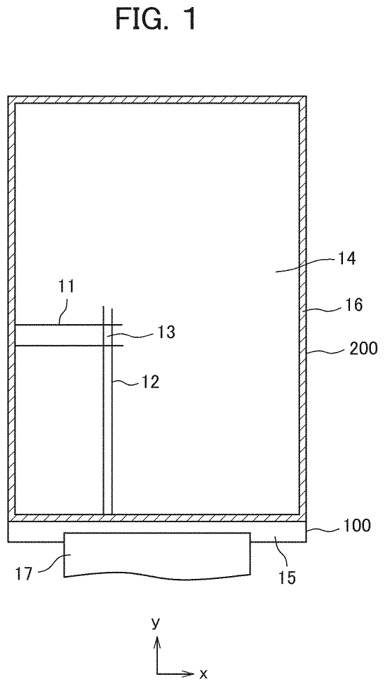

FIG. 1 is a plan view of the liquid crystal display device, to which the present invention is applied. In FIG. 1, the TFT substrate 100 and the counter substrate 200 are adhered to each other by seal material 16; liquid crystal is sandwiched between the TFT substrate 100 and the counter substrate 200. The display area 14 is formed in an area where the TFT substrate 100 and the counter substrate 200 overlap each other.

The scan lines 11 extend in lateral direction (x direction) and are arranged in longitudinal direction (y direction); the video signal lines 12 extend in longitudinal direction and are arranged in lateral direction in the display area 14 of the TFT substrate 100. The pixel 13 is formed in an area surrounded by the scan lines 11 and the video signal lines 12. The TFT substrate 100 is made larger than the counter substrate 200; the terminal area 15 is formed in the area that the TFT substrate 100 does not overlap the counter substrate 200. The flexible wiring substrate 17 connects to the terminal area 15; the driver IC that drives the liquid crystal display device is installed on the flexible wiring substrate 17.

Since the liquid crystal is not self-luminous, a back light is set at the rear of the TFT substrate 100. The liquid crystal generates pictures by controlling the light transmission through each of the pixels. The flexible wiring substrate 17 is bent back to the rear of the back light, thus, overall size of the liquid crystal display device is made compact.

The TFT of the oxide semiconductor, which has low leak current, is used in the display area 14 in the liquid crystal display device according to the present invention. The scan line driving circuit, for example, is formed in the peripheral area in the vicinity of the seal material 16. The TFT of the polysilicon semiconductor, which has a high carrier mobility, is mainly used in the scan line driving circuit; however, the TFT of the oxide semiconductor can also be used in the driving circuit.

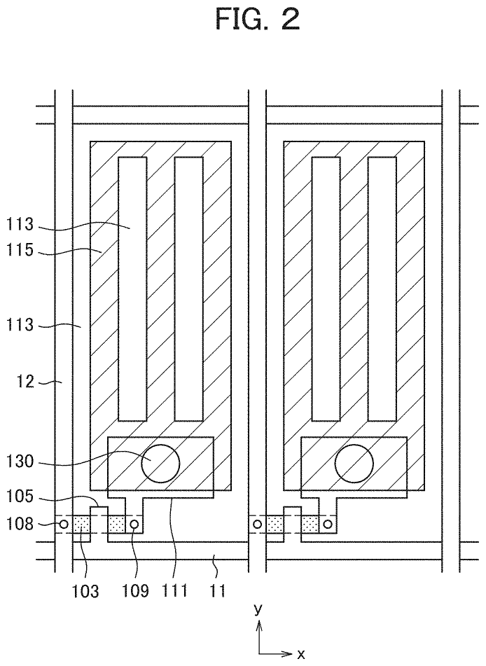

FIG. 2, is a plan view of the pixel 13 in the display area 14. FIG. 2 is a structure of FFS (Fringe Field Switching) mode of the IPS (In Plane Switching) liquid crystal display device. The TFT in figure uses the oxide semiconductor film 103. The TFT of the oxide semiconductor has low leak current, thus, it is suitable for the switching TFT.

In FIG. 2, the scan lines 11 extend in lateral direction (x direction) and are arranged in longitudinal direction (y direction); the video signal lines 12 extend in longitudinal direction and are arranged in lateral direction. The pixel electrode 115 is formed in the area surrounded by the scan lines 11 and the video signal lines 12. In FIG. 2, the oxide semiconductor TFT is formed between the video signal line 12 and the pixel electrode 115. In the oxide semiconductor TFT, the video signal line 12 constitutes the drain electrode, a branch from the scan line 11 constitutes the gate electrode 105. The source electrode 111 of the oxide semiconductor TFT extends toward the pixel electrode 115 and connects with the pixel electrode 115 via through hole 130.

The pixel electrode 115 is formed like comb shaped. The common electrode 113 is formed in a planar shape under the pixel electrode 115 via the capacitance insulating film. The common electrode 113 is formed continuously common to plural pixels. When a video signal is applied to the pixel electrode 115, lines of forces are generated between the pixel electrode 115 and the common electrode 113 through the liquid crystal layer to rotate the liquid crystal molecules, consequently, pictures are formed. In FIG. 2, the light shading film (light shield electrode), which is formed between the TFT and the substrate, is omitted.

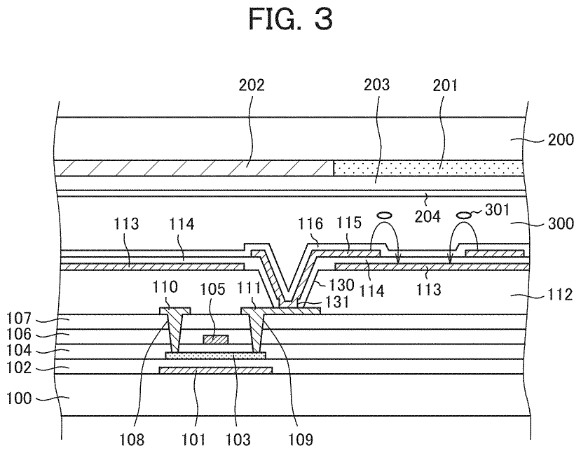

FIG. 3 is a cross sectional view of the liquid crystal display device corresponding to FIG. 2. In FIG. 3, the TFT of the oxide semiconductor is used. The oxide semiconductor TFT is suitable for the switching TFT because of its low leak current.

Examples of the oxide semiconductors are indium gallium zinc oxide (IGZO), indium tin zinc oxide (ITZO), zinc oxide nitride (ZnON), indium gallium oxide (IGO), and so forth. In this embodiment, the IGZO is used for the oxide semiconductor.

In FIG. 3, the light shading film 101 made of metal is formed on the TFT substrate 100, which is made of glass or resin like e.g. polyimide. The metal can be the same metal for e.g. the gate electrode 105, which is formed later. The light shading film 101 is to block the light from the back light for the channel of the TFT, which is formed later.

Another important role of the light shading film 101 is to prevent the oxide semiconductor TFT from being influenced by electric charges accumulated in the substrate 100. Specifically, when the substrate 100 is formed from resin such as polyimide, which easily accumulates electric charges, the TFT strongly influenced by the electric charges in the substrate 100. Applying a certain voltage to the light shield film 101 can prevent the TFT from being influenced by the electric charges accumulated in the substrate 100.

The undercoat film 102 is formed covering the light shading film 101. The undercoat film 102 prevents the oxide semiconductor film 103 from being contaminated by impurities from the TFT substrate 100. The undercoat film 102 is often formed from a laminated film of a silicon oxide (represented by SiO) film and a silicon nitride (represented by SiN) film. Sometimes, an aluminum oxide (represented by A10) film may be further laminated as the undercoat film 102.

In FIG. 3, the oxide semiconductor film 103 that constitutes the TFT is formed on the undercoat film 102. A thickness of the semiconductor film 103 is 10 to 100 nm. The gate insulating film 104 is formed from SiO covering the oxide semiconductor film 103. The gate insulating film 104, which is formed from SiO, supplies oxygen to the oxide semiconductor film 103 to stabilize the characteristics of the channel. The gate electrode 105 is formed on the gate insulating film 104.

The interlayer insulating film 106 is formed from e.g. SiO covering the gate electrode 105. A thickness of the interlayer insulating film 106 is e.g. 150 to 300 nm. The inorganic passivation film 107 is formed from e.g. SiN on the interlayer insulating film 106. A thickness of the inorganic passivation film 107 is e.g. 100 to 200 nm. Through holes 108 and 109 are formed penetrating the inorganic passivation film 107, the interlayer insulating film 106 and the gate insulating film 104 to connect the drain electrode 110 and the oxide semiconductor film 103 and to connect the source electrode 111 and the oxide semiconductor film 103. In FIG. 3, the video signal line 12 works as the drain electrode 110, and the source electrode 111 connects to the pixel electrode 115 via the through holes 130 and 131.

In FIG. 3, the organic passivation film 112 is formed covering the drain electrode 110 and the source electrode 111. The organic passivation film 112 is formed from e.g. acrylic resin. Since organic passivation film 112 has a role as a flattening film and a role to decrease a floating capacitance between the video signal line 12 and the common electrode 113, it is made thick as 2 to 4 microns. The through hole 130 is formed in the organic passivation film 112 to connect the source electrodes 111 and the pixel electrode 115.

The common electrode 113, which is formed from e.g. ITO (Indium Tin Oxide), is formed on the organic passivation film 112. The common electrode 113 is formed in a planar shape in common to plural pixels. The capacitance insulating film 114, made of SiN, is formed on the common electrode 113. The pixel electrode 115, which is formed from transparent conductive film of e.g. ITO, is formed on the capacitance insulating film 114. The pixel electrode 115 is formed comb like shape. The capacitance insulating film 114, sandwiched between the pixel electrode 115 and the common electrode 114, forms a pixel capacitance.

The alignment film 116 is formed covering the pixel electrode 115. The alignment film 116 controls the initial alignment of the liquid crystal molecules 301. The alignment treatment for the alignment film 116 is conducted either by rubbing process or optical alignment process. Since IPS does not need a pre-tilt angle, optical alignment is suitable.

In FIG. 3, the counter substrate 200 is formed opposing to the TFT substrate 100 sandwiching the liquid crystal layer 300. The color filter 201 and the black matrix 202 are formed on the counter substrate 200; the over coat film 203 is formed covering the color filter 201 and the black matrix 202. The alignment film 204 is formed on the overcoat film 203. The alignment treatment for the alignment film 203 is the same as for the alignment film 116 of the TFT substrate 100.

In FIG. 3, when a voltage is applied between the common electrode 113 and the pixel electrode 115, lines of forces as depicted in FIG. 3 are generated to rotate the liquid crystal molecules 301, consequently, a transmittance in the pixel is controlled. Pictures are formed by controlling transmittance of light in each of the pixels.

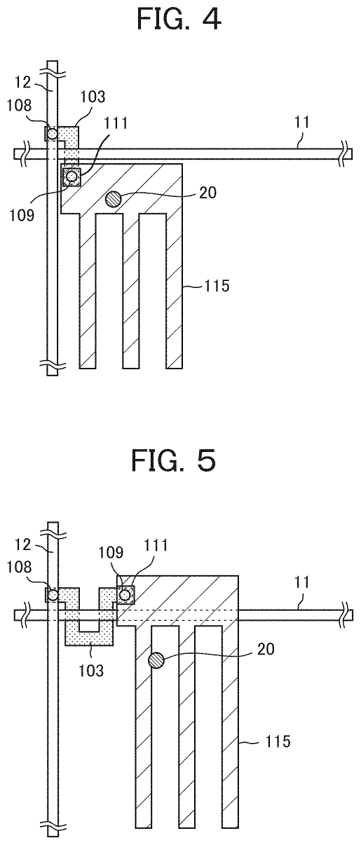

FIG. 4 is a plan view of the pixel, in which foreign substance exists in the vicinity of the TFT of oxide semiconductor 103. The TFT formed from the oxide semiconductor 103 can be made in various layout. The layout of TFT of FIG. 4 differs from the layout of TFT of FIG. 2, however, the equivalent circuit is the same. The shape of the pixel electrode 115 in a plan view is also different from that of FIG. 2, however, the function of the TFT is the same. In FIG. 4, the through hole formed in the organic passivation film 112 is omitted to avoid complexity of the figure.

In FIG. 4, the foreign substance 20 may be fine metal particles generated during sputtering process or fine particles or fine insulating particles mixed into the vicinity of the TFT from the manufacturing apparatus. Such foreign substance 20 deprives the oxide semiconductor film 103 of oxygen, lowers the resistance of the oxide semiconductor film 103, and thus, short the TFT.

As depicted in FIG. 4, the TFT of the oxide semiconductor 103 has a feature that it is defected by the foreign substance 20 in the vicinity of the TFT, even the foreign substance 20 is not on the TFT. The reason is that the foreign substance 20 in a vicinity of the TFT also deprives the oxide semiconductor 103 of oxygen.

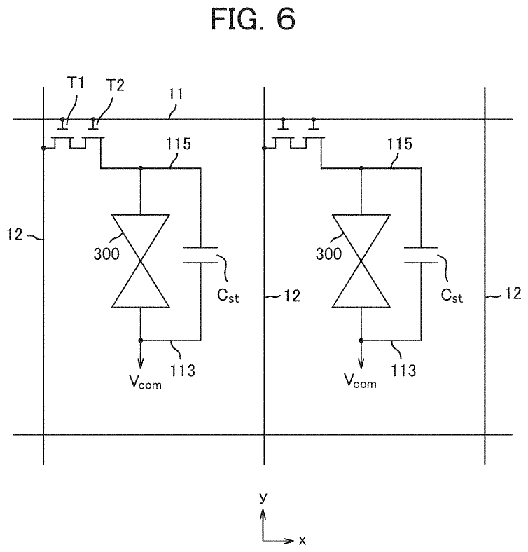

FIG. 5 shows to set two TFTs in series, bending the oxide semiconductor film 103 in a crank shape, to counter measure this problem. FIG. 6 is an equivalent circuit of FIG. 5. As shown in FIGS. 5 and 6, the two TFTs (T1 and T2) are located at one side of the pixel electrode 115. In other words, the two TFTs (T1 and T2) are located in the vicinity of the left hand side video signal line 12. In the structure of FIGS. 5 and 6, two TFTs are closely placed to each other, thus, one foreign substance 20 can deprive the oxide semiconductor film 103, which constitutes two channels of two TFTs, of oxygen; consequently, both of the two TFTs are shorted. Therefore, the structure of FIG. 5 or 6 is not an essential solution for the problem.

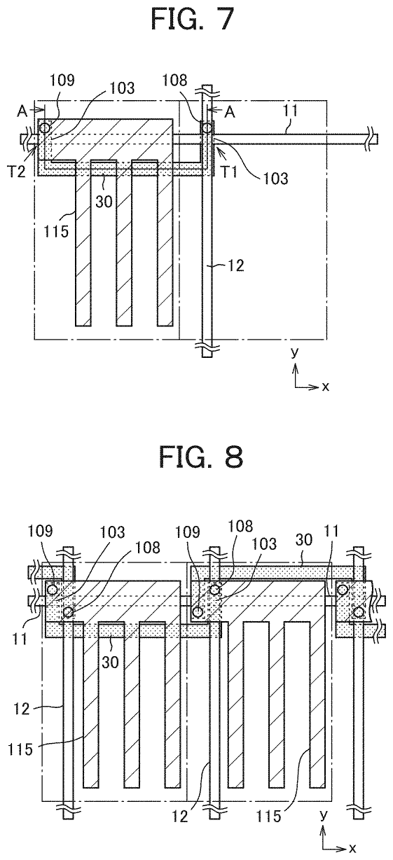

FIG. 7 is a plan view of the pixel according to embodiment 1 that solves the above explained problem. The definition of the pixel can be made in various way; in FIG. 7 for convenience, the pixel is defined by the area that is surrounded by a dashed and dotted line. In FIG. 7, the TFT is formed when the oxide semiconductor film 103 passes under the scan line 11. In FIG. 7, the oxide semiconductor film 103 connects with the video signal line 12 via through hole 108, and extends beneath the video signal line 12; the first TFT T1 is formed where the oxide semiconductor film 103 passes under the scan line 11. Then, the oxide semiconductor film 103 extends in lateral direction across the pixel electrode 115 and bends; the second TFT T2 is formed where the oxide semiconductor film 103 passes again under the scan line 11; the oxide semiconductor film 103 connects with the pixel electrode 115 via through hole 109. In FIG. 7, the through hole 130 formed in the organic passivation film 112 is omitted to avoid complexity of the figure.

In FIG. 7, since the first TFT (T1) and the second TFT (T2) are located across the pixel electrode 115 to each other, the distance between the two TFTs are large. Therefore, when a foreign substance 20 exists near one of the TFTs, only one TFT becomes defective, however, another TFT can survive. Therefore, the pixel can work normally. By the way, the pixel electrode 115 in this case means whole structure of the comb like portions and their connection portions.

In FIG. 7, the oxide semiconductor film 103 extends across the pixel electrode 115; the semiconductor film 103 in this portion is made conductive by ion implantation and so forth. In addition, since the oxide semiconductor film 103 is transparent, a transmittance of the pixel is not substantially decreased even the oxide semiconductor film 103 exists across the pixel electrode 115. In the meantime, the oxide semiconductor film 103, which is given conductivity, to connect the first TFT (T1) and the second TFT (T2) is depicted as the connecting line 30 in FIG. 7.

FIG. 8 is a plan view in which the pixel electrode 115 and the oxide semiconductor 103 and so forth in the neighboring pixel are simultaneously shown. In FIG. 8, in the left hand side pixel, the oxide semiconductor film 103, which is given conductivity, that connects two TFTs is located below the scan line 11 in y direction; in the right hand side pixel, the oxide semiconductor film 103, which is given conductivity, that connects two TFTs is located above the scan line 11 in y direction. Consequently, two oxide semiconductor films 103 can be formed on the same layer.

The structure of FIG. 8 can be expressed alternatively as follows. The pixel electrode 115 exists between the first video signal line 12 and the second video signal line 12; the first TFT of the oxide semiconductor 103 connects with the second video signal line 12 in the vicinity of the second video signal line 12, which is at the right hand side of the pixel electrode 115; the second TFT of the oxide semiconductor 103 connects with the pixel electrode 115 in the vicinity of the first video signal line 12, which is at the left hand side of the pixel electrode 115. The connection line 30 is formed from the oxide semiconductor film 103 that is given conductivity. It is expressed as that the connecting line 30 formed from the oxide semiconductor film 103 that is given conductivity extends across the pixel electrode 115 or extends in parallel with the scan line 11.

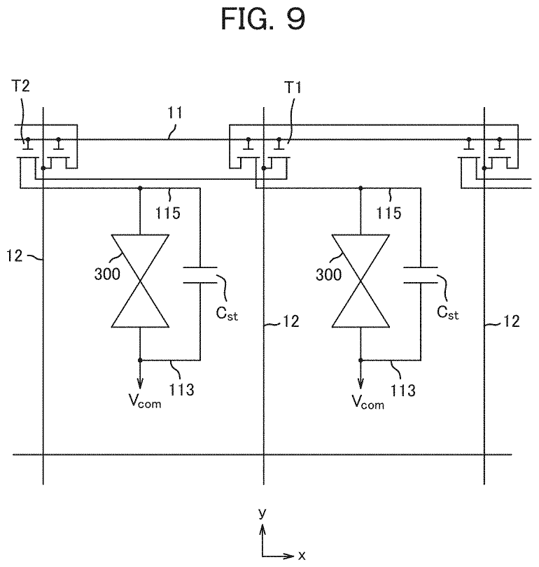

FIG. 9 is an equivalent circuit of FIG. 8. The first TFT (T1) is actually formed overlapping the video signal line 12, however, in FIG. 9, the first TFT (T1) is set deviated in lateral direction from the video signal line 12 for easy understanding. In FIG. 9, the liquid crystal layer 300 exists between the pixel electrode 115 and the common electrode 113. The storage capacitance Cst, which maintains the pixel voltage, is formed between the pixel electrode 115 and the common electrode 113. In FIG. 9, the first TFT (T1), which connects with video signal line 12, connects with the second TFT (T2) via the connecting line 30 that laterally extends across the pixel electrode 115; the second TFT (T2) connects with the pixel electrode 115. The first TFT (T1) and the second TFT (T2) are separated by a size of the pixel in x direction.

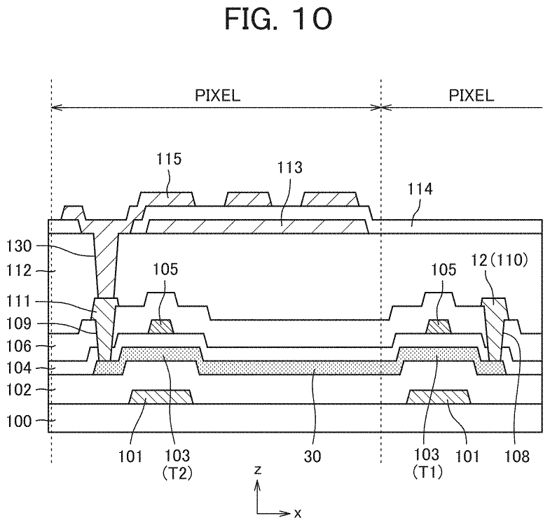

FIG. 10 is a cross sectional view of FIG. 7 along the line A-A. The layer structure of FIG. 10 is the same as explained in FIG. 3; however, the structure above the pixel electrode 115 is omitted in FIG. 10. The inorganic passivation film 107 in FIG. 3 is also omitted in FIG. 10. The feature of FIG. 10 is that the first TFT (T1), which connects with the video signal line 12, and the second TFT (T2), which connects with the pixel electrode 115 are apart in x direction by a size of one pixel. The first TFT (T1) and the second TFT (T2) are connected by the connecting line 30, which is made from the oxide semiconductor film 103 that is given conductivity. Since the oxide semiconductor film 103 is transparent, it does not decrease transmittance of the pixel even it is formed under the pixel electrode 115.

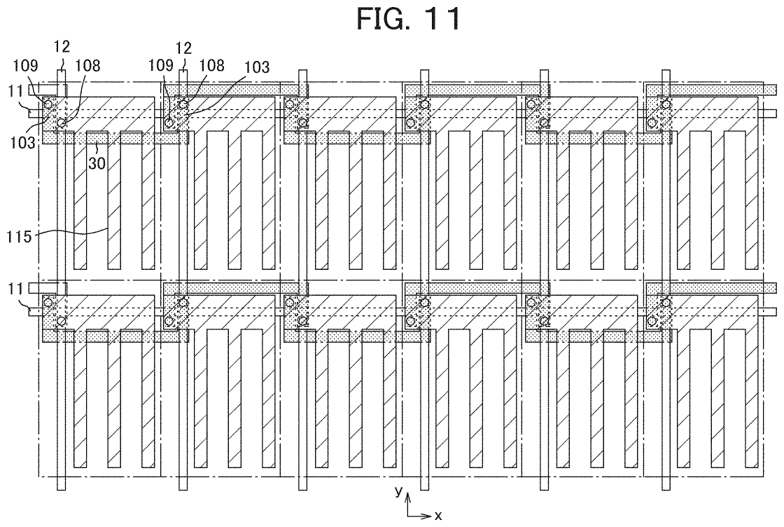

FIG. 11 is a plan view in which pixels are shown in six columns and in two rows. FIG. 11 is a repetition of the structure of FIG. 8. Therefore, the first TFT (T1) and the second TFT (T2) are separated by a size of one pixel in x direction everywhere in the display area. Consequently, there is only little probability that the first TFT (T1) and the second TFT (T2) simultaneously are defected.

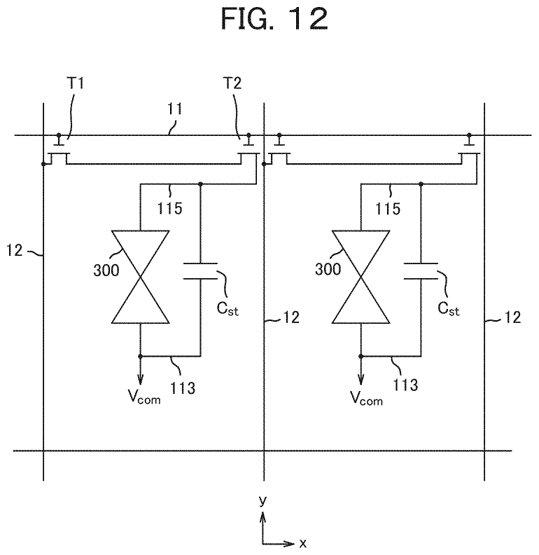

FIG. 12 is an equivalent circuit of another example of embodiment 1. FIG. 12 differs from FIG. 9 in that the video signal is supplied to each of the pixels 115 from the video signal line 12 of left hand side. Therefore, the positions of T1 and T2 in FIG. 12 are exchanged in FIG. 9. However, it is the same in FIG. 12 that the first TFT (T1) and the second TFT (T2) are separated by a size of one pixel in x direction. Consequently, the distance between the first TFT (T1) and the second TFT (T2) can be made large. The structure of FIG. 12 may have a merit in certain layout.

### Embodiment 2

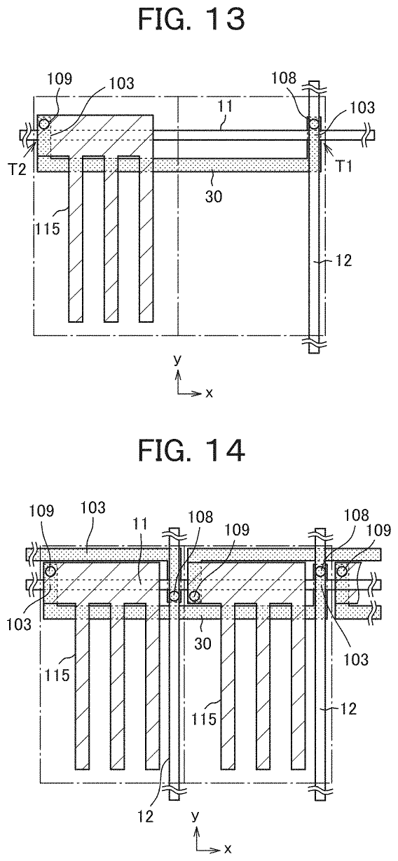

Embodiment 2 is a structure in which the first TFT (T1) and the second TFT (T2) are separated by a size of two pixels in x direction. Thus, a probability of occurrence of defects pixel can be further decreased. FIG. 13 is a plan view of embodiment 2. In FIG. 13, the dashed and dotted line defines the pixel for convenience. In FIG. 13, the first TFT (T1), which connects with video signal line 12, is located near the video signal line 12 at right hand side of the neighboring pixel in x direction; the second TFT (T2), which connects with the pixel electrode 115, is located at an edge of the left hand side of the pixel. In other words, the first TFT (T1) and the second TFT (T2) are separated by a size of two pixels in x direction. Alternatively, it is expressed as the first TFT (T1) and the second TFT (T2) sandwich two pixels in x direction. Therefore, probability that the first TFT (T1) and the second TFT (T2) simultaneously become defective is further decreased compared with embodiment 1.

FIG. 14 is a plan view in which the pixel electrode 115 and the oxide semiconductor 103 in the neighboring pixel are additionally shown. In FIG. 14, the connection line 30 formed from the oxide semiconductor film 103, which is given conductivity, connects the two TFTs; the connection line 30 extends across two pixel electrodes 115 in x direction, however it does not decrease a transmittance of the pixels because the oxide semiconductor film 103 is transparent. The oxide semiconductor films 103, which are given conductivity, are located above and below the scan line in y direction alternately in x direction; thus, both of the oxide semiconductor films 103 can be formed on the same layer.

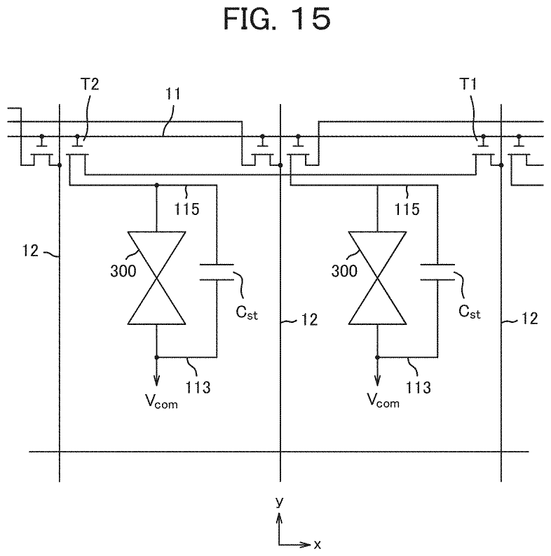

FIG. 15 is an equivalent circuit of FIG. 14. The first TFT (T1), which connects with the video signal line 12, is actually formed overlapping the video signal line 12, however, in FIG. 15, the first TFT (T1) is set deviated in lateral direction from the video signal line 12 for easy perception. As depicted in FIG. 15, the first TFT (T1) and the second TFT (T2) sandwich the two pixel electrodes 115 in x direction. In other words, the first TFT (T1) and the second TFT (T2) are apart by a distance of two pixels in x direction.

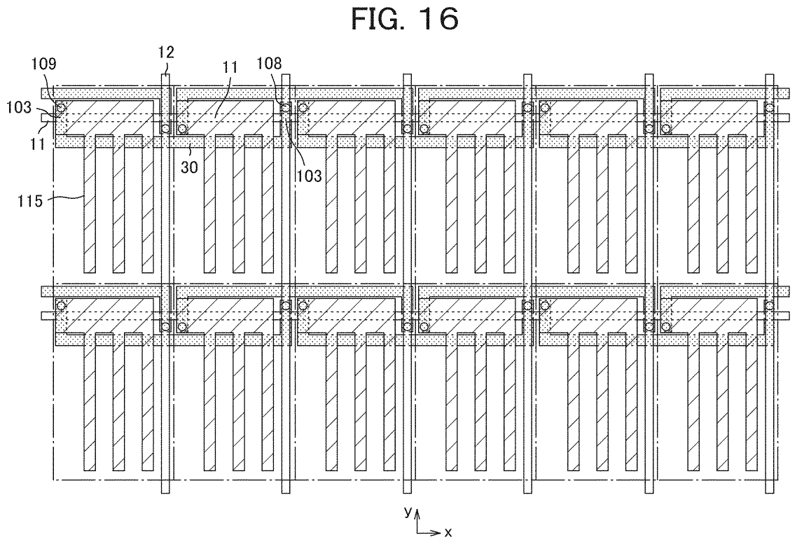

FIG. 16 is a plan view in which pixels are shown in six columns and in two rows according to embodiment 2. FIG. 16 is a repetition of the structure of FIG. 14. Therefore, the first TFT (T1) and the second TFT (T2) are separated by a size of two pixels in x direction everywhere in the display area. Consequently, there is less provability that the first TFT (T1) and the second TFT (T2) are simultaneously defective even compared with the structure of embodiment 1.

### Embodiment 3

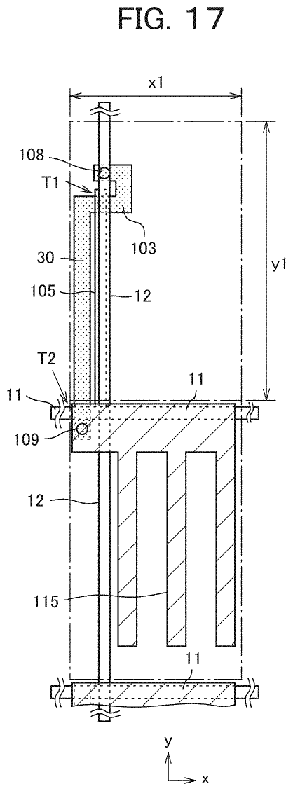

Embodiment 3 is a structure in which two TFTs (T1 and T2) are set apart at upper side of the pixel and at lower side of the pixel in longitudinal direction. FIG. 17 is a plan view of embodiment 3. In FIG. 17, the area surrounded by dashed and dotted line is one pixel for convenience. In FIG. 17, the oxide semiconductor film 103 connects with the video signal line 12 via through hole 109 at the upper pixel in y direction from the subject pixel, in which the pixel electrode 150 is drawn; the oxide semiconductor film 103 bends like crank and crosses the gate electrode 105, which is a branch of the scan line 11; the first TFT (T1) is formed at this portion.

The oxide semiconductor film 103, which conductivity is given, extends in lower direction (in y direction) along the video signal line 12 and connects with the pixel electrode 115 via through hole 109. The second TFT (T2) is formed where the oxide semiconductor film 103 passes under the scan line 11. In FIG. 17, the oxide semiconductor film 103, which is given conductivity, is depicted as the connecting line 30, which connects the first TFT (T1) and the second TFT (T2). Generally, a longitudinal dimension y1 of the pixel is larger than a lateral dimension x1 of the pixel, for example, y1 is approximately 3 times of x1. Therefore, if a larger distance between the first TFT (T1) and the second TFT (T2) is required, the structure of FIG. 17 has a merit.

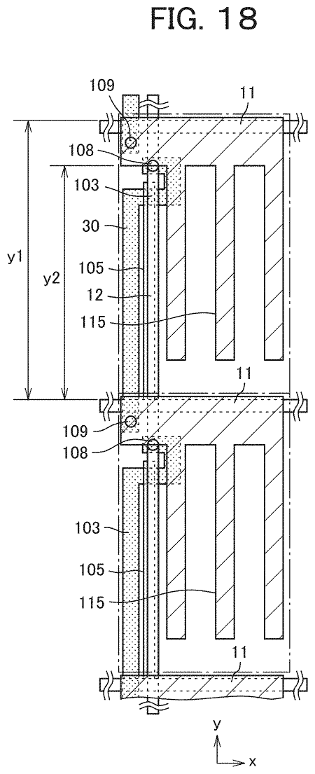

FIG. 18 is a plan view in which the pixel electrode 115 and the oxide semiconductor film 103 are drawn in the neighboring pixel. In FIG. 18, the shapes of the oxide semiconductor films 103 in the upper pixel and in the lower pixel are the same. Even in such a structure, the oxide semiconductor films 103 in any of the pixels can be formed on the same layer.

The feature of FIGS. 17 and 18 has a long gate electrode 105 branched off from the scan line 11. The length y2 of the branch is 50% or more and 70% or less of the longitudinal dimension y1 of the pixel. The larger the y2, the less provability that two TFTs become defective simultaneously. On the other hand, a larger area that the gate electrode 105 overlaps with the video signal line 12 causes larger capacitance between the lines; thus, operating speed becomes low.

It is conceivable to make apart the video signal line 12 and the gate electrode in x direction so that the overlapping area is made small; however, since the video signal line 12 and the gate electrode 105 are formed from metal, a transmittance of the pixel decreases. Therefore, the amount of deviation in x direction between the video signal line 12 and the gate electrode 105 is determined in considering the operating speed and the transmittance of the pixel.

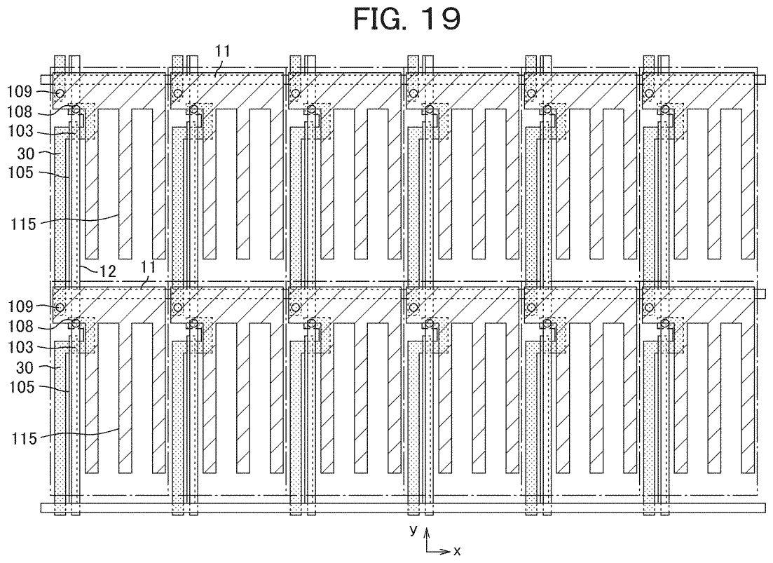

FIG. 19 is a plan view in which pixels are shown in six columns and in two rows. FIG. 19 is a repetition of the structure of FIG. 18. Therefore, the first TFT (T1) and the second TFT (T2) are separated by a half or more of longitudinal dimension y1 of the pixel. Consequently, there is only little probability that the first TFT (T1) and the second TFT (T2) become simultaneously defective.

### Embodiment 4

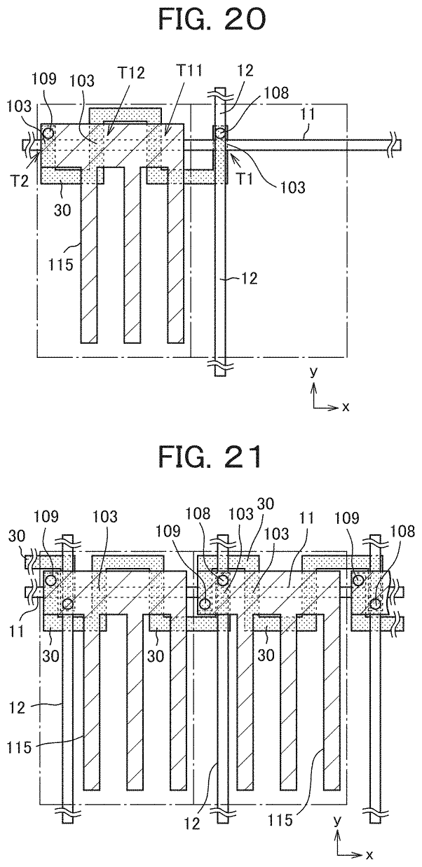

Embodiment 4 is a case where four or more oxide semiconductor TFTs are formed in one pixel. FIG. 20 is a plan view of representative structure of embodiment 4. The basic structure of FIG. 20 is the same as FIG. 7 of embodiment 1; however, in FIG. 20, two TFTs of T11 and T12 exist between the first TFT T1, which connects with the video signal line 12, and the second TFT T2, which connects with the pixel electrode 115.

In FIG. 20, the oxide semiconductor film 103, which is given conductivity, does not straightly extend across the pixel; the oxide semiconductor film 103 bends in crank shape to pass under the scan line 11; thus, two additional TFTs T11 and T12 are formed. Consequently, four TFTs are formed in one pixel in FIG. 20. Therefore, even a foreign substance 20 exists in the pixel, if any one of four TFTs survives, the pixel can work normally. In FIG. 20, the oxide semiconductor film 103, which is given conductivity, is depicted as connecting line 30 that connects two TFTs.

FIG. 21 is a plan view in which the pixel electrode 115 and the oxide semiconductor 103 in the neighboring pixel are simultaneously shown. In FIG. 21, since the oxide semiconductor films 103 do not overlap each other in neighboring pixels, all the oxide semiconductor film 103 can be formed on the same layer. All the pixels in the display area of embodiment 4 can be constituted by pixel structure of FIG. 21.

FIGS. 20 and 21 correspond to FIG. 7 of embodiment 1; however, the structure of embodiment 2 as depicted in FIG. 13 can be applied to embodiment 4. In this case, six oxide semiconductor TFTs can be formed in one pixel if necessary. Even numbers of TFTs are increased when the oxide semiconductor film 103 is bent in crank shape to pass under the scan line 11 to form the TFTs.

### Embodiment 5

In embodiment 1, the first TFT (T1) and the second TFT (T2), which are set at opposite sides of the pixel to each other, are connected by the oxide semiconductor film 103, which conductivity is given. The oxide semiconductor 103, even conductivity is given, has high resistance compared with metal, thus, there occurs a case in which sufficient ON current is not achieved. In embodiment 5, to counter measure the problem, the two TFTs (T1 and T2) are connected by metal line to avoid decrease in ON current. The metal in this case includes alloy. Namely, the oxide semiconductor films 103 that constitute the first TFT (T1) and the second TFT (T2) are formed in island shape.

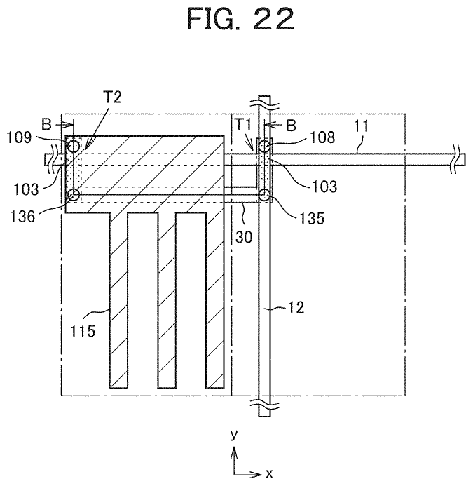

FIG. 22 is a plan view of the pixel according to embodiment 5. In FIG. 22, the pixel electrode 115, the first TFT (T1) and the second TFT (T2) and so forth are the same as FIG. 7 of embodiment 1. FIG. 22 duffers from FIG. 7 in that the oxide semiconductor films 103 that constitute the first TFT (T1) and the second TFT (T2) are connected by connecting line 30 made from metal. The connecting line 30 of metal is formed from the same material as the gate electrode 105 and is patterned simultaneously with the gate electrode 105. The connecting line 30 formed from metal connects with the oxide semiconductor film 103 of the first TFT (T1) via through hole 135 and connects with the oxide semiconductor film 103 of the second TFT (T2) via through hole 136.

This structure gives a high ON current, however, as shown in FIG. 22, transmittance of the pixel decreases because the connecting line 30 of metal crosses the pixel electrode 115. To avoid a decrease in transmittance or to mitigate a decrease in transmittance, the connecting line 30 of metal may be set in an area where back light is not irradiated or a width of the connecting line 30 of metal may be made narrower.

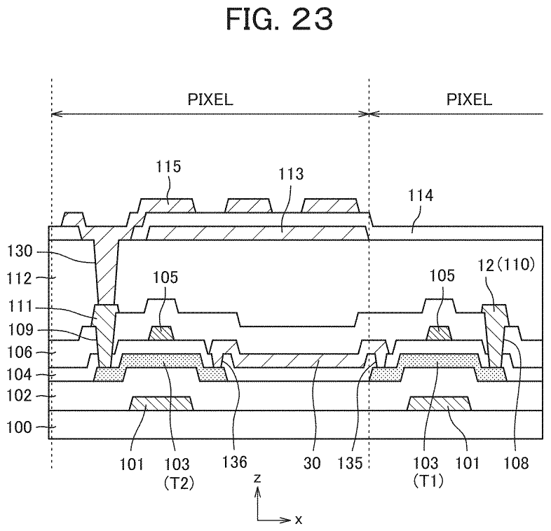

FIG. 23 is a cross sectional view of FIG. 22 along the line B-B. FIG. 23 differs from FIG. 10 of embodiment 1 in that the oxide semiconductor film 103 of the first TFT (T1) and the oxide semiconductor film 103 of the second TFT (T2) are connected by the connecting line 30 of metal, formed on the gate insulating film 104, via through hole 135 and through hole 136. As explained in embodiment 1, simultaneous defects of the first TFT (T1) and the second TFT (T2) because of existence of foreign substance 20 can be avoided because the first TFT (T1) and the second TFT (T2) are kept away from each other.

The structure of embodiment 5 can be adapted to the structures of embodiments 2, 3, and 4. In those cases, too, a tradeoff between ON current and transmittance of the pixel is necessary.

### Embodiment 6

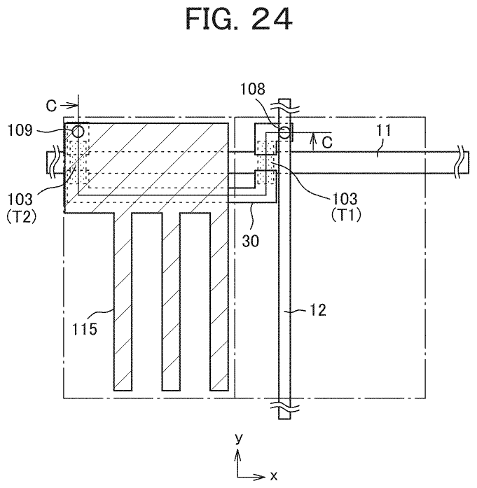

In embodiments 1-5 explain the structures when the TFTs of oxide semiconductor 103 is a top gate type. The present invention can be applied when the TFT of oxide semiconductor 103 is a bottom gate type. FIG. 24 is a plan view of the pixel when two TFTs of oxide semiconductor 103 are bottom gate type. When the TFTs are bottom gate type, the connection line 30, which connects the two TFTs, is made from metal.

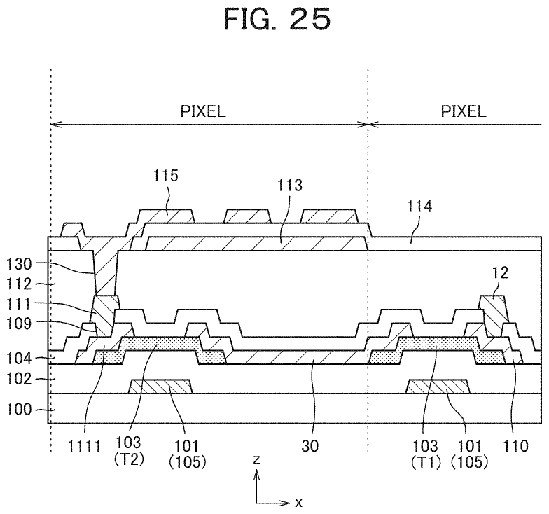

FIG. 25 is a cross sectional view of FIG. 24 along the line C-C. In the case of bottom gate type, the scan line 11 works as the gate electrode 105 and the shield electrode 101, therefore, the number of layers is less than that of e.g. FIG. 7. In other words, a top gate insulating film does not exist in FIG. 25 compared with FIG. 7. The oxide semiconductor film 103 that constitutes the first TFT (T1) and the oxide semiconductor film 103 that constitutes the second TFT (T2) are connected by metal connection line 30. The drain electrode 110 or the source electrode 1111 of the first TFT and the second TFT are formed simultaneously with the metal connection line 30.

The oxide semiconductor films 103 that constitute the first TFT (T1) and the second TFT (T2) are covered by metal except channel portions. The metal deprives the oxide semiconductor film 103 of oxygen, therefore, the oxide semiconductor films 103 that are covered by metal are made conductive.

The bottom gate type TFT explained in FIGS. 24 and 25 is applicable to embodiment 2, embodiment 3, and so forth. As explained above, even in the bottom gate type TFTs, as like in the top gate type TFTs, if two TFTs (T1 and T2) are set apart with necessary distance, the chance that two TFTs (T1 and T2) simultaneously become defective can be avoided.

### Embodiment 7

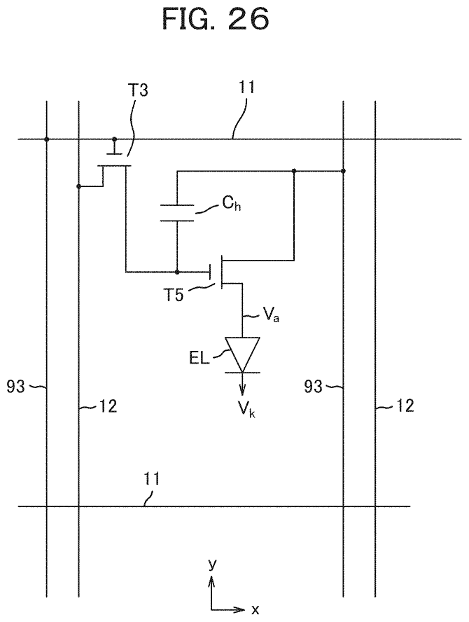

Embodiments 1-6 explain when the present invention is applied to the liquid crystal display device. The present invention is applicable to the organic EL display device, too. FIG. 26 is an equivalent circuit of the pixel of the organic EL display device. In FIG. 26, the video signal lines 12 and the power lines 93 extend in longitudinal direction (y direction) and are arranged in lateral direction (x direction); the scan lines 11 extend in lateral direction and are arranged in longitudinal direction. The pixel is formed in the area surrounded by the scan lines 11 and the video signal lines 12 or the power lines 93.

In FIG. 26, the control TFT (T5) controls the current that flows in the organic EL layer (EL), which emits light. The drain of the control TFT (T5) connects with the power line 93; the holding capacitance (Ch) is connected between the power line 93 and the gate of the control TFT (T5). The gate of control TFT (T5) connects with the source of the switching TFT (T3). The gate of the switching TFT (T3) connects with the scan line 11 and the drain of the switching TFT (T3) connects with the video signal line 12.

In FIG. 26, when a gate of the switching TFT (T3) is set ON, a video signal is supplied from the video signal line 12 to one electrode of the holding capacitance Ch; consequently, charges are supplied from the power line 93. As a result, the gate of the control TFT (T5) holds a certain voltage, thus, corresponding current flows from the control TFT (T5) to the organic EL layer (EL).

As depicted in FIG. 26, two TFTs (T3 and T5) exist in a pixel of the organic EL display device. As explained in embodiment 1, if a foreign substance 20 exists in the pixel, a resistance of the channel of TFT formed from the oxide semiconductor film 103 is lowered; consequently, the TFT becomes defective. If both of the switching TFT (T3) and the control TFT (T5) are formed from the oxide semiconductor 103, the same phenomenon occurs in both TFTs.

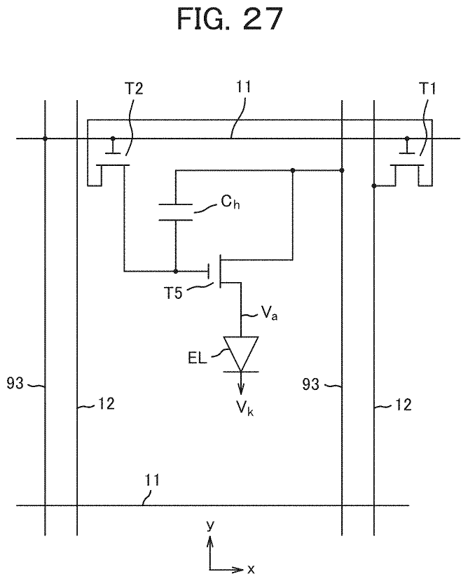

FIG. 27 is a structure that solves this problem. In FIG. 27, two switching TFTs are connected in series; the first TFT (T1) is set near the video signal line 12 which is located at right hand side of the pixel; the second TFT (T2) is set near the video signal line 12 which is located at left hand side of the pixel. This structure is the same as embodiment 1, which is for the liquid crystal display device. Since the two switching TFTs (T1 and T2) are set apart with a distance, simultaneous defection of the two switching TFTs (T1 and T2) due to foreign substance 20 can be avoided. The layout of two switching TFTs can be the same or an equivalent of embodiment 1. The structures of embodiments 2 and 3, which are other examples to set apart two switching TFTs with a distance to each other, can be applicable to embodiment 7 as embodiment 1 is applied to embodiment 7.

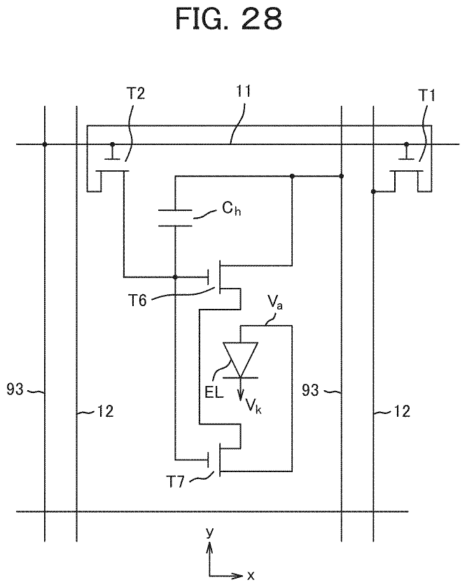

When the control TFT (T5) is formed from the oxide semiconductor 103, the problem caused by foreign substance 20 is the same for the switching TFT (T3). FIG. 28 is a structure to counter measure the problem caused by a foreign substance 20. In FIG. 28, the control TFT (T5) is divided into two; the first control TFT (T6) connects with the power line 93 and the second control TFT (T7) connects with Anode Va; the first control TFT (T6) is set above the organic EL layer in y direction and the second control TFT (T7) is set below the organic EL layer in y direction. A probability that two control TFTs (T6 and T7) are simultaneously shorted due to the existence of a foreign substance is substantially lowered by the structure in which the first control TFT (T6) and the second control TFT (T7) are separated to each other with a distance across the organic EL layer (EL) in y direction.

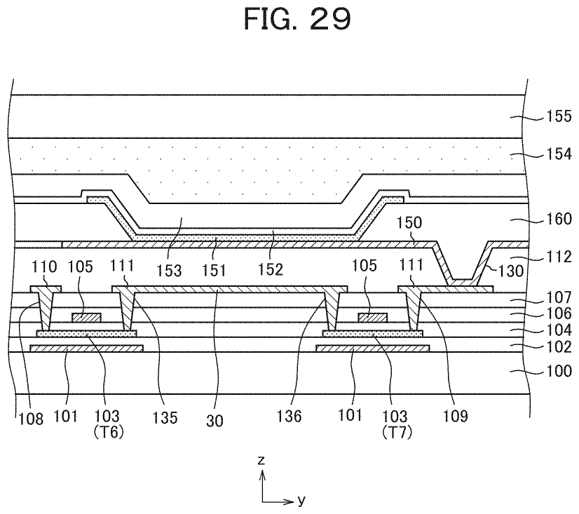

FIG. 29 is a cross sectional view of the display area of the organic EL display device including the control TFTs (T6 and T7) of the oxide semiconductor 103. In FIG. 29, the lateral direction is y direction. The layer structure of FIG. 29 is the same as the liquid crystal display device of FIG. 3 from forming the TFT by oxide semiconductor 103, forming the organic passivation film 112 covering the TFT, and forming through hole 130 to connect the TFT and the lower electrode 150. The TFTs (T6 and T7) of FIG. 29, however, are control TFTs while the TFT of FIG. 3 is a switching TFT. However, the layer structures are the same.

FIG. 29 differs from FIG. 3 in that the first control TFT (T6) and the second control TFT (T7) are set apart to each other with a distance across the organic EL layer in y direction. The first control TFT (T6) and the second control TFT (T7) are connected by the metal connecting line 30, which is formed on the same layer as the drain electrode 110 and the source electrode 111.

In FIG. 29, the lower electrode 150, which works as an anode, is formed on the organic passivation film 112. The bank 160, which has a hole, is formed on the lower electrode 150. The organic EL layer 151 as light emitting layer is formed in the hole of the bank 160. The upper electrode 152 as a cathode is formed on the organic EL layer 151. The upper electrode 152 is formed in common to plural pixels. The protective layer 153, which includes SiN film and so forth, is formed covering the upper electrode 152. The circular polarizing film 155 is attached via the adhesive 154 on the protective film 153.

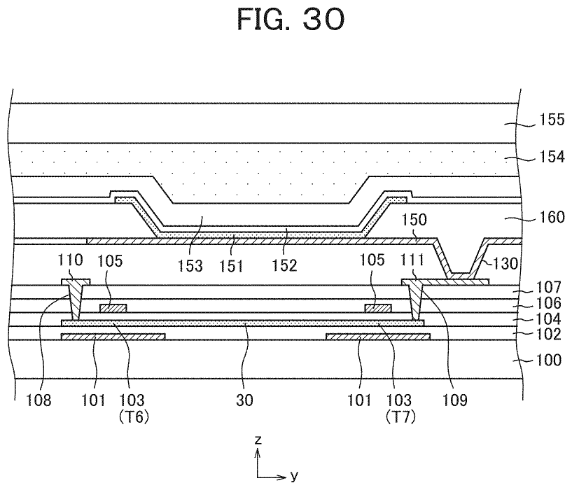

FIG. 30 is a cross sectional view in which the connecting line 30, which connects the first control TFT (T6) and the second control TFT (T7), is formed from the oxide semiconductor film 103 that conductivity is given. If a large current in the organic EL layer is not necessary, process for making the connection line 30 from metal can be omitted by adopting the structure of FIG. 30.

As shown in FIGS. 28, 29 and 30, in the organic EL display device too, the control TFT (T5) can be divided into two control TFTs (T6 and T7) set apart across the anode (corresponds to the pixel electrode); consequently, necessary distance between the two control TFTs (T6 and T7) can be taken. Consequently, the danger that two TFTs become simultaneously defective due to a foreign substance 20 can be significantly decreased.

### Embodiment 8

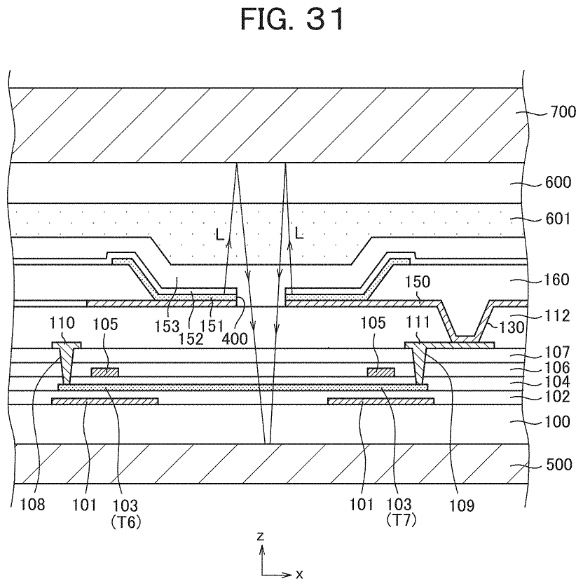

The present invention can be applied to several semiconductor devices as sensor devices as well as the display devices. There are many kinds of sensor devices. FIG. 31 shows an example that a similar structure as the organic EL display device is used as a photo sensor, which uses the organic EL display device as a light emitting element. FIG. 31 is a cross sectional view in which the light receiving element 500 is set under the TFT substrate 100 in the display area (light emitting area) of the organic EL display device explained in FIG. 30. The face plate 600 formed from a transparent glass substrate or a transparent resin substrate is set on the upper surface of the light emitting element via the adhesive 601. The measuring object 700 is set on the face plate 600.

In the light emitting element, a light emitting area is formed from the organic EL layer 151, the lower electrode 150 and the upper electrode 152. In the middle of the light emitting area, the window 400 exists, where light can pass. By the way, a reflecting electrode is formed at the bottom of the lower electrode 150, therefore, the light L emitted from organic EL layer 151 goes upward.

In FIG. 31, the light L, emitted from the organic EL layer 151, is reflected from the measuring object 700; the light L goes down through the window 400, and is received by the light receiving element 500; thus, the measuring object 700 is recognized. If there is no measuring object 700, the reflecting light is not generated, therefore, current does not flow in the light receiving element 500. Therefore, the apparatus can measure whether the measuring object 700 exists.

In FIG. 31, the oxide semiconductor film 103 that is given conductivity connects two control TFTs; however, since the oxide semiconductor film 103 is transparent, it does not hinder the light L. If the connecting line 30, which connects the two control TFTs (T6 and T7), is formed from metal, the metal connecting line 30 can be set to avoid the route of the light, or a width of the metal connecting line 30 can be made narrow to suppress a decrease in transmittance of the light L.

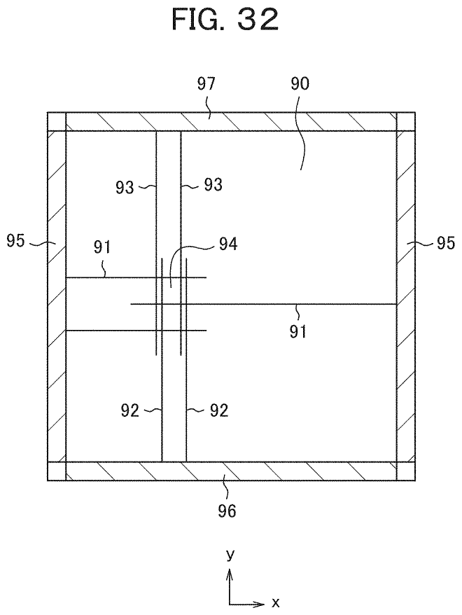

FIG. 32 is a plan view of the photo sensor, in which the sensor elements of FIG. 31 are set in matrix in the detecting area 90. In FIG. 32, the scan lines 91 extend in lateral direction (x direction) from the scan line driving circuits 95 set at both sides of the detecting area 90. The signal lines 92 extend in longitudinal direction (y direction) from the signal driving circuit 96, which is set below the detecting area 90 in longitudinal direction. The power lines 93 extend in longitudinal direction (−y direction) from the power circuit 97, which is set above the detecting area 90 in longitudinal direction. The sensor element 94 is formed in the area that is surrounded by the scan lines 91 and the signal lines 92 or surrounded by the scan lines 91 and the power lines 93.

By the way, the photo sensor of this embodiment can detect not only an existence of an object, but also a two dimensional image by detecting intensity of the light reflected from the measuring object 700. Further, color images or spectral images can be taken by conducting a spectral sensing. The definition of the sensor is determined by a size of the sensor element 94 shown in FIG. 32; however, the size of sensor element can be adjusted by driving plural sensor elements 94 integrally according to necessity.

The example shown in FIGS. 31 and 32 is that the structure similar to the organic EL display device is applied to the photo sensor; however, the structure of the present invention can be applied to photo sensors that have different measuring methods. Further, the present invention is applicable to other sensors having a substrate of semiconductor devices as a capacitance sensor, and so forth.

What is claimed is:

1. A semiconductor device comprising:
a scan line extending in a first direction,
a first signal line extending in a second direction, which crosses the first direction,
a second signal line, which extends parallel to the first signal line,
an electrode disposed between the first signal line and the second signal line,
wherein a first TFT connects with the second signal line in a vicinity of the second signal line, a second TFT connects with the electrode in a vicinity of the first signal line,
the first TFT and the second TFT are formed from oxide semiconductors,
the first TFT and the second TFT are connected in series.

2. The semiconductor device according to claim 1,
wherein, the first TFT and the second TFT are connected by a connecting line that is parallel to the scan line.

3. The semiconductor device according to claim 2,
wherein, the connecting line is formed from an oxide semiconductor that conductivity is given.

4. The semiconductor device according to claim 2,
wherein, the connecting line is formed from metal or alloy.

5. The semiconductor device according to claim 2,
wherein the connecting line is formed across the electrode in the first direction.

6. A semiconductor device comprising:
a scan line extending in a first direction,
a first signal line extending in a second direction, which crosses the first direction,
a second signal line, which extends parallel to the first signal line,
a third signal line, which extends parallel to the second signal line,
a first electrode, disposed between the first signal line and the second signal line,
a second electrode, disposed between the second signal line and the third signal line,
wherein a first TFT connects with the third signal line in a vicinity of the third signal line, a second TFT connects with the first electrode in a vicinity of the first signal line,
the first TFT and the second TFT are formed from oxide semiconductors,
the first TFT and the second TFT are connected in series.

7. The semiconductor device according to claim 6,
wherein, the first TFT and the second TFT are connected by a connecting line that is parallel to the scan line.

8. The semiconductor device according to claim 7,
wherein, the connecting line is formed from an oxide semiconductor that conductivity is given.

9. The semiconductor device according to claim 7,
wherein, the connecting line is formed from metal or alloy.

10. The semiconductor device according to claim 7,
wherein the connecting line is formed across the first electrode and the second electrode in the first direction.

11. A semiconductor device comprising:
a first scan line, a second scan line and a third scan line extending in a first direction and arranged with a distance L1 to each other,
a first signal line and a second signal line extending in a second direction that crosses the first direction with a distance W to each other,
an electrode formed between the second scan line and the third scan line and between the first signal line and the second signal line,
wherein a first TFT that connects with the first signal line exists near the first signal line and between the first scan line and the second scan line,
a second TFT that connects with the electrode exists near an intersection of the first signal line and the second scan line,
provided a distance between a center of the second scan line and a center of a channel of the first TFT in the second direction is L2,
L2≥0.5L1
the first TFT and the second TFT are formed from oxide semiconductors,
the first TFT and the second TFT are connected in series.

12. The semiconductor device according to claim 11,
provided a distance between a center of the second scan line and a center of a channel of the first TFT in the second direction is L2,
L2≥0.7L1

13. The semiconductor device according to claim 11,
wherein, the first TFT and the second TFT are connected by a connecting line that is parallel to the first signal line.

14. The semiconductor device according to claim 13,
wherein, the connecting line is formed from an oxide semiconductor that conductivity is given.

15. The semiconductor device according to claim 13,
wherein, the connecting line is formed from metal or alloy.

16. The semiconductor device according to claim 1,
wherein the first TFT and the second TFT are top gate type TFTs.

17. The semiconductor device according to claim 1,
wherein the first TFT and the second TFT are bottom gate type TFTs.

18. The semiconductor device according to claim 1,
wherein the semiconductor device is a liquid crystal display device.

19. The semiconductor device according to claim 1,
wherein the semiconductor device is an organic EL display device.

20. The semiconductor device according to claim 1,
wherein the semiconductor device is a photo sensor device.
